(19) United States
(12) Patent Application Publication
(10) Pub. No.: US 2021/0246369 A1
(43) Pub. Date: Aug. 12, 2021

(54) RED LUMINESCENT MATERIAL AND CONVERSION LED

(71) Applicant: OSRAM Opto Semiconductors GmbH, Regensburg (DE)

(72) Inventors: Markus Seibald, Kaufering (DE); Dominik Baumann, Munich (DE); Christiane Stoll, Schwabmuenchen (DE); Hubert Huppertz, Innsbruck (AT)

(21) Appl. No.: 17/268,969

(22) PCT Filed: Oct. 22, 2019
(86) PCT No.: PCT/EP2019/078726

§ 371 Date: Feb. 17, 2021

(30) Foreign Application Priority Data
Oct. 24, 2018 (DE) 10 2018 218 159.4

(51) Int. Cl. C09K 11/61; C01B 33/10; H01L 33/50

(52) U.S. Cl. CPC C09K 11/616; C01B 33/103; H01L 33/502; C01P 2002/72; C01P 2002/76; C01P 2002/77; C01P 2002/54

(57) ABSTRACT

The present disclosure provides a phosphor having an empirical formula Li₂SiF₆:Mn⁴⁺, a conversion LED including the phosphor, and a method of making the phosphor by solid-state synthesis.

### REFERENCE TO RELATED APPLICATIONS

The present application is a national stage entry according to 35 U.S.C. § 371 of PCT Application No.: PCT/EP2019/078726 filed on Oct. 22, 2019, which claims priority to German Patent Application No.: 10 2018 218 159.4 filed on Oct. 24, 2018, both of which are incorporated by reference herein in their entirety.

### TECHNICAL FIELD

The disclosure relates to a phosphor and to a conversion LED including the phosphor.

### BACKGROUND

In white light-emitting conversion LEDs as used in general lighting, the red component of the white overall radiation is generated by the conversion of blue primary light from a semiconductor layer sequence to longer-wave, red radiation by means of an inorganic phosphor. A crucial role is played here by the shape and position of the emission band in the red spectral region. The human eye is fundamentally less sensitive to red radiation than to green radiation, for example. The lower the energy or the greater the wavelength in the wavelength range above 555 nm, the poorer/less efficient the ability to perceive red radiation, for example. In a white light-emitting conversion LED, however, the red spectral regions, for example, deep red spectral regions having long wavelengths may be particularly important when the conversion LED is to have a high color rendering index (CRI) in combination with high luminous efficacy of radiation (LER) and low correlated color temperature (CCT). Typical red phosphors for these applications are based on Eu²⁺ or Ce³⁺ emission, and these elements are introduced into organic host structures in which they then cause longer-wave emissions under absorption of blue light. These phosphors generally have broad emission spectra or emission bands. Accordingly, in the case of red-emitting phosphors, many photons are inevitably also converted to those spectral regions (large wavelengths; e.g. >650 nm) that can be perceived only very inefficiently by the human eye. This leads to a significant reduction in efficiency of the conversion LED in relation to eye sensitivity. In order to solve this problem, it is possible to attempt a short-wave shift in the emission spectrum by variations in the chemical composition of the host structure, i.e. to increase the integral overlap with the eye sensitivity curve. As a result of the Gaussian distribution of the photons emitted, however, this also leads to a reduction in the photon count in the desired red spectral region, and the abovementioned criteria can accordingly no longer be fulfilled.

Phosphors such as nitridolithoaluminate “SrLiAl₃N₄:Eu²⁺” (discussed in WO 2013/175336 A1; Narrow-band red-emitting Sr[LiAl₃N₄]:Eu²⁺ as a next-generation LED-phosphor material, Nature Materials 2014; P. Pust et al.) already have extremely narrow emission bands with FWHM<55 nm, which leads to a reduction in those converted photons in the long-wave region of the visible spectrum (long-wave flank of the emission band) that are perceived very inefficiently by the human eye. At the same time, however, the emission maximum of SrLiAl₃N₄:Eu²⁺ at about 650 nm is so far into the deep-red region that conversion LEDs including this phosphor as the only red component have barely any efficiency advantage, if any, over solutions including broader-band phosphors. The efficiency losses here are dominant over the CRI gain (R9). Another phosphor, SrMg₃SiN₄:Eu²⁺ (discussed in “Toward New Phosphors for Application in Illumination-Grade White pc-LEDs: The Nitridomagnesosilicates Ca[Mg₃SiN₄]:Ce³⁺, Sr[Mg₃SiN₄]:Eu²⁺ and Eu[Mg₃SiN₄],” Chemistry of Materials 2014, S. Schmiechen et al.), shows a blue-shifted, likewise extremely narrow emission band (FWHM <45 nm) that has its emission maximum at about 615 nm and hence within an ideal range for red phosphors. Disadvantageously, this compound shows significant thermal quenching, such that it is barely possible to observe any emission even at room temperature. Employment in conversion LEDs is thus impossible.

There is thus a need for red-emitting phosphors having a minimum spectral width of emission (“full width at half maximum”, FWHM) in order to keep the number of photons small in spectral regions of low eye sensitivity and simultaneously to emit many photons in the desired red spectral region.

### SUMMARY

In some aspects, the present disclosure provides a phosphor that emits radiation in the red spectral region and has a small spectral emission width. Additionally, the present disclosure provides a conversion LED including the phosphor described here.

In some aspects, the present disclosure provides a phosphor, a process for preparing a phosphor, and a conversion LED. Further aspects and developments of the disclosure are provided in the features described herein.

A phosphor is specified, for example, a red-emitting phosphor.

In at least one aspect, the phosphor may include a phase having the empirical formula Li₂SiF₆:Mn⁴⁺. The phosphor may include Li₂SiF₆:Mn⁴⁺. In other words, the phosphor may have the empirical formula Li₂SiF₆:Mn⁴⁺. Mn⁴⁺ may replace Si⁴⁺.

Phosphors are described here and hereinafter in terms of empirical formulae. In the empirical formulae specified, it is possible that the phosphor includes further elements, for instance in the form of impurities, where these impurities taken together may have a maximum proportion by weight of the phosphor of not more than one per mille or 100 ppm (parts per million) or 10 ppm.

In at least one aspect, the phosphor has the empirical formula Li₂Si₁₋ₓMnₓF₆ where 0.001≤x≤0.1, optionally, 0.005≤x≤0.08, or 0.01≤x≤0.06.

The phosphor is an Mn⁴⁺-doped hexafluorosilicate. A known phosphor from this material class is K₂SiF₆:Mn⁴⁺. The emission spectrum of this phosphor features narrow emission bands, where the full width at half maximum of these emission bands is below 10 nm and hence much smaller than corresponding emission bands, for example for Eu²⁺-doped phosphors. K₂SiF₆:Mn⁴⁺ may be prepared by a precipitation reaction in aqueous hydrofluoric acid (HF) (discussed in “Efficient Mn (IV) Emission in Fluorine Coordination,” A. G. Paulusz, J. Electrochem. Soc.: Solid-State Science and Technology 1973, 942). Reactants used are, for example, K₂CO₃ or KF (which also forms through dissolution of K₂CO₃ in HF), and SiO₂ and a manganese source.

The inventors of the present disclosure have found that, in some aspects, the synthesis for K₂SiF₆:Mn⁴⁺ may not be applied to the preparation of the phosphor Li₂SiF₆:Mn⁴⁺. In other words, the phosphor Li₂SiF₆:Mn⁴⁺ may not form from a precipitation reaction in aqueous hydrofluoric acid (HF), for example, using the reactants Li₂CO₃, SiO₂ and a manganese source.

To the inventors' knowledge, there are no known publications to date that disclose a successful synthesis of Li₂SiF₆:Mn⁴⁺. The inventors have succeeded in synthesizing the phosphor of the formula Li₂SiF₆:Mn⁴⁺ for the first time and in detailing an implementable route to the synthesis thereof.

It has been found that Li₂SiF₆:Mn⁴⁺ on excitation with primary radiation has an emission or secondary radiation with a peak wavelength in the red spectral region. The peak wavelength is, for example, about 630 nm. With a surprisingly short-wave emission maximum of about 630 nm, the emission is within a region for red phosphors. The position of the emission maximum and the simultaneously small full width at half maximum of the emission bands results in emission of many photons in the desired visible red spectral region, and minimization of the converted photons in the long-wave red region of the visible spectrum that are perceived very inefficiently by the human eye. The phosphor is thus of excellent suitability for a conversion LED that emits white overall radiation, since it is possible to achieve a high color rendering index and a high luminous efficacy of radiation (LER) of the overall radiation.

It has additionally been found that, surprisingly, the luminous efficacy of radiation (LER) of Li₂SiF₆:Mn⁴⁺ is 7% higher than for K₂SiF₆:Mn⁴⁺, since the emission maximum of Li₂SiF₆:Mn⁴⁺ is at a somewhat shorter wavelength compared to that of K₂SiF₆:Mn⁴⁺.

The “peak wavelength” or “emission maximum” refers in the present context to the wavelength in the emission spectrum of a phosphor at which the maximum intensity in the emission spectrum lies.

In at least one aspect, the phosphor crystallizes in a trigonal crystal system. For example, the phosphor crystallizes in the P321 space group. In other words, the phosphor crystallizes in the Na₂SiF₆ type.

The known phosphor K₂SiF₆:Mn⁴⁺, by contrast, crystallizes in the cubic Fm-3m space group. In other words, the phosphor crystallizes in the K₂PtCl₆ type.

In a further aspect, Mn⁴⁺ may be present in mol % amounts of from 0.1 mol % to 10 mol %, 0.5 mol % to 8 mol % or 1 mol % to 6 mol %. Molar percentages for Mn⁴⁺ here and hereinafter are based on the molar proportions of Si in the phosphor.

In at least one aspect, the phosphor is capable of absorbing primary radiation from the UV to blue spectral region and converting it to secondary radiation within the red spectral region.

Moreover, the phosphor, in at least one aspect, has a full width at half maximum of the emission bands below 10 nm. For example, the full width at half maximum of the emission band having the maximum intensity (emission maximum, peak wavelength) is below 15 nm.

The full width at half maximum (FWHM) is understood here and hereinafter to mean the spectral width at half the height of the maximum of an emission peak or of an emission band or emission line.

The phosphor Li₂SiF₆:Mn⁴⁺, on excitation with primary radiation from the UV to blue spectral region, emits secondary radiation with a peak wavelength in the red spectral region at about 630 nm. The emission bands of the phosphor may have a full width at half maximum below 10 nm and hence a high light yield as a result of a large overlap with the human eye sensitivity curve having a maximum at 555 nm. This means that the phosphor can be used to provide particularly efficient conversion LEDs.

The inventors have thus recognized that it is possible to provide a phosphor having advantageous properties that could not be provided to date.

A process for preparing a phosphor is provided. All definitions and aspects of the phosphor are also applicable to the process for preparation thereof, and vice versa.

In at least one aspect, the phosphor having the empirical formula Li₂SiF₆:Mn⁴⁺ is prepared by a solid-state synthesis. The inventors have found that the phosphor surprisingly may not be able to prepared by a wet-chemical precipitation reaction from HF.

In at least one aspect, the solid-state synthesis is performed under elevated pressure and at elevated temperature. An elevated pressure is understood to mean a pressure above 1 bar, and elevated temperature to mean a temperature above 25° C.

In at least one aspect, the solid-state synthesis is performed under a pressure of 25 kbar to 85 kbar and within a temperature range between 500° C. and 1000° C.

In at least one aspect, reactants used in the solid-state synthesis are Li₂SiF₆ and A₂MnF₆ with A=Li, Na, K, Rb or Cs. Reactants used in the solid-state synthesis are for example, Li₂SiF₆ and Cs₂MnF₆ or Li₂SiF₆ and K₂MnF₆.

In at least one aspect, a molar ratio of the molar amount of Li₂SiF₆ to the molar amount of A₂MnF₆ is between 1.000:0.200 and 1.000:0.001, for example 1:0.059.

In at least one aspect, a molar ratio of the molar amount of Li₂SiF₆ to the molar amount of K₂MnF₆ is between 1.000:0.200 and 1.000:0.001, for example 1:0.059.

The disclosure further relates to a conversion LED. For example, the conversion LED includes the phosphor. All details and definitions relating to the phosphor and to the process which are applicable for preparing the phosphor are also applicable to the conversion LED, and vice versa.

In at least one aspect, the conversion LED includes a semiconductor layer sequence. The semiconductor layer sequence is set up to emit electromagnetic primary radiation.

In at least one aspect, the semiconductor layer sequence includes at least one III-V compound semiconductor material. The semiconductor material is, for example, a nitride compound semiconductor material, such as AlₙIn₁₋ₙ₋ₘGaₘN where, in each case, 0≤n≤1, 0≤m≤1 and n+m ≤1. The semiconductor layer sequence here may include dopants and additional constituents. For the sake of simplicity, however, constituents of the semiconductor layer sequence, i.e. Al, Ga, In and N, are shown by way of example, even though these may be replaced and/or supplemented to some degree by small amounts of further substances. For example, the semiconductor layer sequence may be formed from InGaN.

The semiconductor layer sequence includes an active layer having at least one pn junction and/or having one or more quantum well structures. In the operation of the conversion LED, electromagnetic radiation is generated in the active layer. A wavelength or the emission maximum of the radiation is optionally in the ultraviolet and/or visible region, for example, at wavelengths between 300 nm and 470 nm inclusive.

The conversion LED may be set up to emit white or colored light.

In combination with the phosphor present in the conversion LED, the conversion LED is may be set up to emit red light in full conversion or white light in partial or full conversion. Such conversion LEDs may be suitable for applications where a high color rendering index (e.g. R9) may be required, as in general lighting or background lighting, for example of displays suitable for representation of large color spaces.

The conversion LED includes a conversion element. For example, the conversion element includes the phosphor. The phosphor at least partly or fully converts the electromagnetic primary radiation to electromagnetic secondary radiation in the red spectral region.

In at least one aspect, the conversion element or conversion LED may not include any further phosphor aside from the phosphor. The phosphor may be set up to fully convert the primary radiation. The overall radiation from the conversion LED in this aspect is in the red region of the electromagnetic spectrum.

In at least one aspect, the conversion element or conversion LED includes a further red-emitting phosphor as well as the phosphor. The conversion element may also include the phosphor and the further red-emitting phosphor. The phosphors may be set up to fully convert the primary radiation. The overall radiation from the conversion LED in this aspect is in the red region of the electromagnetic spectrum. For example, the further red-emitting phosphor may have the formula Sr[Al₂Li₂O₂N₂]:Eu. Sr[Al₂Li₂O₂N₂]:Eu may crystallize in the tetragonal P4₂/m space group. The further phosphor allows the color locus of the overall radiation to be matched as required. In addition, it is thus possible to achieve particularly high color saturation and efficiency that typically may not be achieved by the use of just one phosphor.

In at least one aspect, the conversion element includes a second and/or third phosphor as well as the phosphor. The conversion element may include further phosphors as well as the phosphor and the second and third phosphors. For example, the phosphors are embedded in a matrix material. Alternatively, the phosphors may also be present in a converter ceramic.

The conversion LED may include a second phosphor for emission of radiation from the green spectral region.

Additionally or alternatively, the conversion LED may include a third phosphor. The third phosphor may be set up for emission of radiation from the yellow spectral region. In other words, the conversion LED may then include at least three phosphors: a yellow-emitting phosphor, a green-emitting phosphor and the red-emitting phosphor. The conversion LED is set up for full conversion or partial conversion, where the primary radiation in the case of full conversion may be selected from the UV to blue spectral region and in the case of partial conversion from the blue region. The resulting overall radiation from the conversion LED is, for example, white mixed radiation.

Additionally or alternatively, the conversion LED may include a fourth phosphor. The fourth phosphor may be set up for emission of radiation from the blue spectral region. The conversion LED may then include at least three phosphors: a blue-emitting phosphor, a green-emitting phosphor and the red-emitting phosphor. The conversion LED is set up for full conversion, where the primary radiation in the case of full conversion may be selected from the UV spectral region. The resulting overall radiation from the conversion LED is, for example, white mixed radiation.

Yellow, blue and green phosphors are known to the person skilled in the art and are not detailed separately here.

Phosphors present in addition to the phosphor may increase the color rendering index. Further phosphors in addition to the second, third and/or fourth phosphor are not ruled out. The higher the color rendering index, the more true, or true to nature, the color impression perceived.

### Working Example

The phosphor of the disclosure having the empirical formula Li₂SiF₆:Mn⁴⁺ was prepared by means of solid-state synthesis in a multi-anvil high-pressure press at pressures of 5.5 GPa (55 kbar) and high temperatures. The reactants used were Li₂SiF₆ and K₂MnF₆ in a molar ratio of 1:0.059. The pressure of 55 kbar was built up within 145 minutes. The temperature was increased at a heating rate of 75° C. per minute to 750° C. and the temperature of 750° C. was maintained for 150 minutes. Thereafter, the temperature was cooled down to 350° C. at a cooling rate of 2.2° C. and the phosphor was subsequently quenched to room temperature (25° C.) Subsequently, the pressure was reduced within 145 minutes.

Studies by means of x-ray powder methods show that the phosphor can be prepared in good quality (see FIG. 3).

### BRIEF DESCRIPTION OF THE DRAWINGS

In the following, the phosphor and the lighting device described herein are explained in more detail in conjunction with non-limiting aspects and the associated figures.

FIG. 1A shows the unit cell of cubic K₂SiF₆:Mn⁴⁺ (space group no. 225; Fm-3m).

FIG. 1B shows the unit cell of the phosphor Li₂SiF₆:Mn⁴⁺.

FIG. 2 shows an emission spectrum of the phosphor Li₂SiF₆:Mn⁴⁺.

FIG. 3 shows a PXRD comparison (Mo-kα₁ radiation) of Li₂SiF₆:Mn⁴⁺ with a simulation of Li₂SiF₆.

FIG. 4 shows an emission spectrum of the phosphor Li₂SiF₆:Mn⁴⁺ compared to K₂SiF₆:Mn⁴⁺ and Cs₂MnF₆.

FIG. 5 shows the luminous efficacy of radiation of Li₂SiF₆:Mn⁴⁺ compared to K₂SiF₆:Mn⁴⁺.

FIG. 6 shows absorption spectra and emission spectra of two comparative examples.

The figures and the proportions of the elements depicted in the figures relative to each other are not to be considered as true to scale. Rather, individual elements may be displayed in an exaggeratedly large format for better presentation and/or comprehensibility.

### DETAILED DESCRIPTION

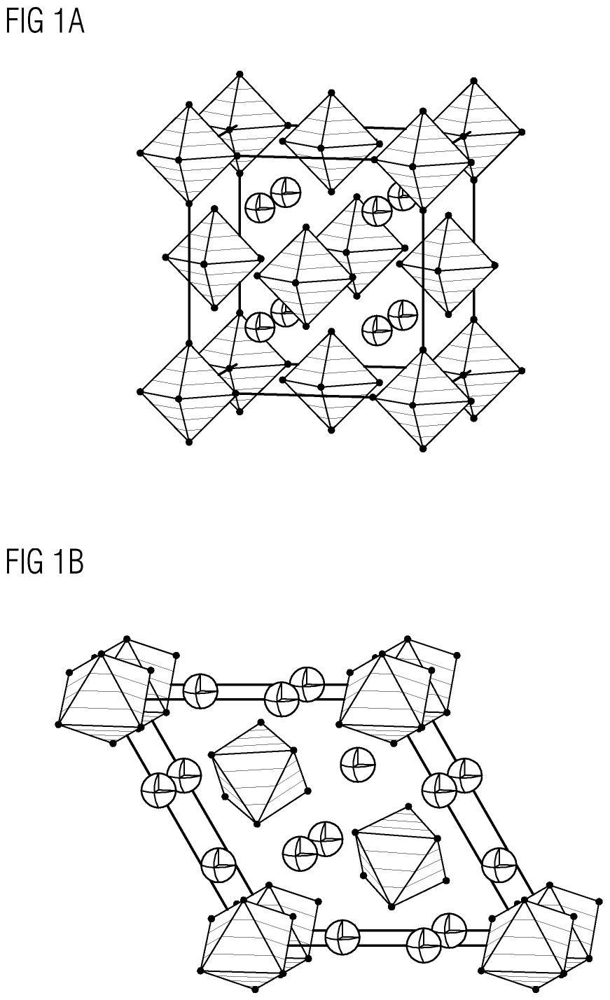

FIG. 1A shows the unit cell of the crystal structure of K₂SiF₆:Mn⁴⁺, which crystallizes in the cubic Fm-3m space group. The K atoms are shown as unfilled ellipsoids, the F atoms as filled circles, and SiF₆ octahedra in hatched form with Si in the center and F at the vertices. Si has been partly replaced by Mn (not shown). K₂SiF₆:Mn⁴⁺ crystallizes in the K₂PtCl₆ type in the Fm-3m space group (no. 225). The unit cell shows a cubic metric with a lattice parameter a=8.134(1) Å.

FIG. 1B shows the unit cell of the crystal structure of Li₂SiF₆:Mn⁴⁺. The Li atoms are shown as unfilled ellipsoids, the F atoms as filled circles, and SiF₆ octahedra in hatched form with Si in the center and F at the vertices. Si has been partly replaced by Mn (not shown), such that Mn⁴⁺ is octahedrally surrounded by F atoms. Compared to K₂SiF₆:Mn⁴⁺, Li₂SiF₆:Mn⁴⁺ surprisingly crystallizes in the Na₂SiF₆ type in the P321 space group (no. 150); the unit cell shows a trigonal metric with lattice parameters a=8.2190(1) Å and c=4.5580(1) Å.

A comparison of FIGS. 1A and 1B shows clearly that the crystal structures differ significantly from one another; for example, the SiF₆ octahedra in the cubic K₂SiF₆:Mn⁴⁺ are uniformly oriented, whereas these assume different spatial orientations in Li₂SiF₆:Mn^{4+.}

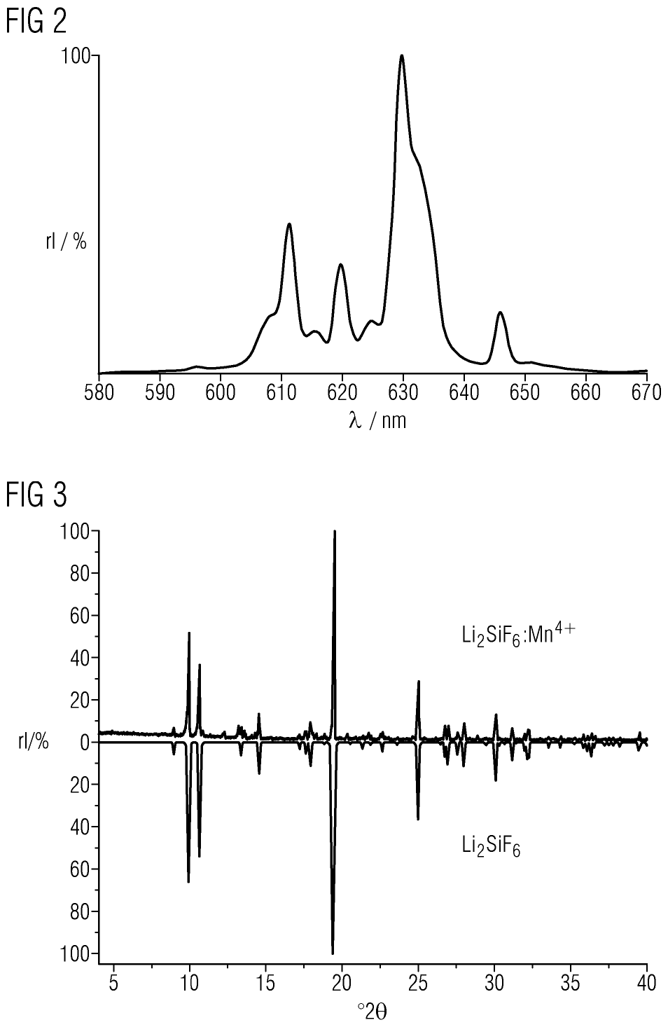

FIG. 2 shows the emission spectrum of a single grain of the phosphor Li₂SiF₆:Mn⁴⁺ on excitation with blue laser light (λ_{exc}=450 nm).

FIG. 3 shows a comparison of x-ray diffractograms (PXRD) (Mo-Kα₁ radiation). What is shown is the measured x-ray diffractogram of the phosphor Li₂SiF₆:Mn⁴⁺ compared to a simulation of Li₂SiF₆ based on data from literature (discussed in “Pressure-supported crystal growth and single-crystal structure determination of Li₂SiF6,” Zeitschrift für Kristallographie 2014, E. Hinteregger et al.). Good agreement is apparent, and so these studies by means of x-ray powder methods show that the phosphor Li₂SiF₆:Mn⁴⁺ was preparable in good quality.

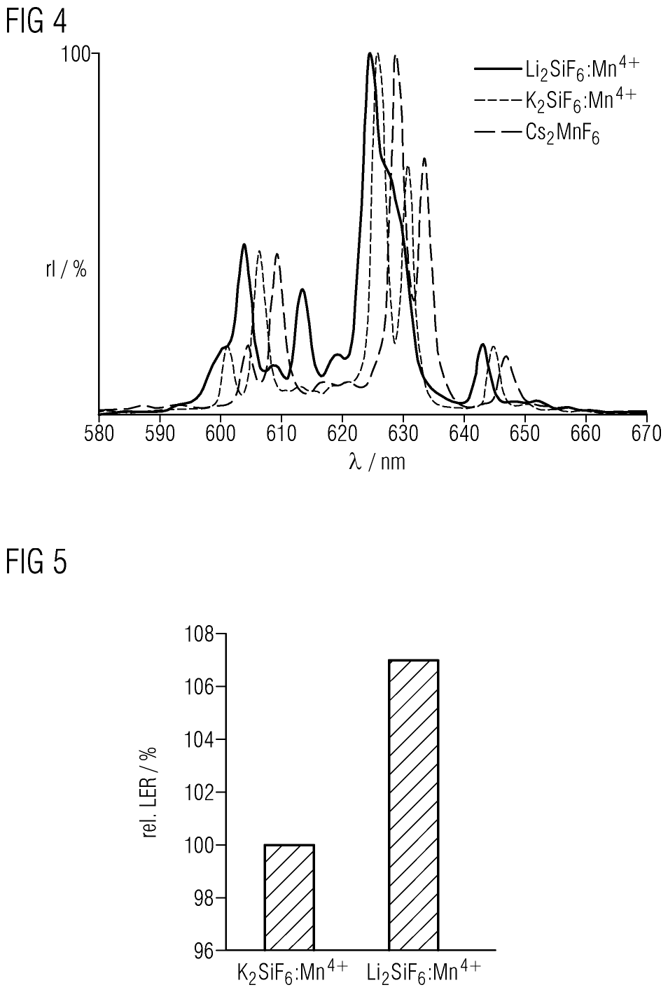

FIG. 4 shows an emission spectrum of the phosphor Li₂SiF₆:Mn⁴⁺ compared to that of K₂SiF₆:Mn⁴⁺ and of Cs₂MnF₆. The phosphors were excited with blue laser light λ_{exc}=450 nm.

Just like K₂SiF₆:Mn⁴⁺, Cs₂MnF₆ crystallizes in the K₂PtCl₆ type. This relationship is likewise apparent from the emission spectra. Thus, the two compounds in the K₂PtCl₆ type, i.e. K₂SiF₆:Mn⁴⁺ and Cs₂MnF₆, show a high level of matches in the number and shape of the individual peaks, but differ from the emission of the phosphor Li₂SiF₆:Mn⁴⁺. For example, the peak at about 618 nm for Li₂SiF₆:Mn⁴⁺ is absent in the case of the two other phosphors K₂SiF₆:Mn⁴⁺ and Cs₂MnF₆. Since the eye sensitivity curve has a large (negative) slope in the region of the here present emission maxima of the three phosphors, even small shifts in the emission band (CIE color coordinates x and y) result in distinctly different spectral efficiency, as shown in the table below and FIG. 5.

| | | | x; y | | |
|---|---|---|---|---|---|
| | | | coordinates | | |
| | | | in the CIE | LER / lm | rel. |
| | λ_{dom*} / nm | λₘₐₓ / nm | color space | Wₒₚₜ⁻¹ | LER / % |
| Li₂SiF₆: Mn⁴⁺ | 618 | 630 | 0.688; 0.312 | 218 | 107 |
| K₂SiF₆: Mn⁴⁺ | 621 | 631 | 0.693; 0.307 | 204 | 100 |
| Cs₂MnF₆ | 622 | 634 | 0.696; 0.304 | 187 | 92 |

*dominant wavelength

The dominant wavelength is a way of describing non-spectral (polychromatic) light mixtures in terms of spectral (monochromatic) light that creates a similar perception of hue. In the CIE color space, the line that connects a point for a particular color and the point CIE-x=0.333, CIE-y=0.333 can be extrapolated in such a way that it meets the outline of the space at two points. The point of intersection closer to said color represents the dominant wavelength of the color as the wavelength of the pure spectral color at this point of intersection. The dominant wavelength is thus the wavelength that is perceived by the human eye.

The optical data in the table show that the phosphor Li₂SiF₆:Mn⁴⁺ has the greatest luminous efficacy of radiation compared to K₂SiF₆:Mn⁴⁺ and Cs₂MnF₆:Mn⁴⁺.

The comparison of relative luminous efficacy of radiation between Li₂SiF₆:Mn⁴⁺ and K₂SiF₆:Mn⁴⁺ is shown in the form of a graph in FIG. 5.

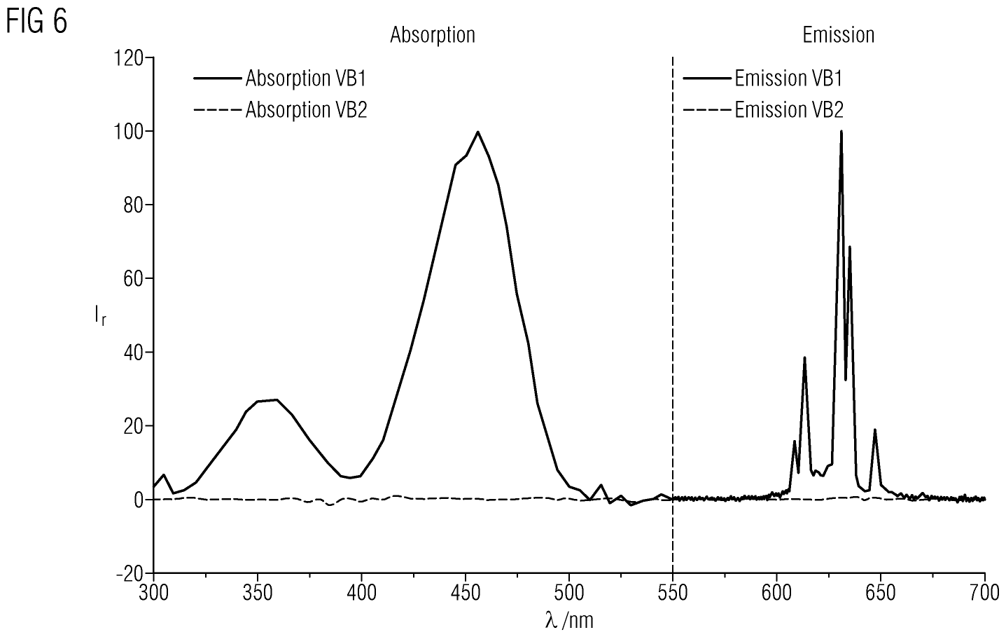

FIG. 6 shows absorption spectra and emission spectra of a comparative example VB2 and K₂SiF₆:Mn⁴⁺. The data for K₂SiF₆:Mn⁴⁺ correspond to those from literature (discussed in “Mn⁴⁺-Activated Red Photoluminescence in K₂SiF₆ Phosphor,” Journal of the Electrochemical Society 2008, T. Takahashi et al.).

Two identical experiments (precipitation reaction in 60% HF) were conducted, with successful preparation of K₂SiF₆:Mn⁴⁺ (comparative example 1 (VB1)) in one case and, in the other case, in which the only change was the replacement of the K source (K₂CO₃) by the corresponding Li source (Li₂CO₃), no formation of the doped target compound Li₂SiF₆:Mn⁴⁺ (comparative example 2 (VB2)). After dissolution of the SiO₂ in hydrofluoric acid, the respective carbonate was added until the solution was saturated (cf. table below).

TABLE
Reactants for synthesis of VB1 (K₂SiF₆: Mn⁴⁺) and VB2. Reaction
in each case in 60% HF and with use of 35% H₂O₂ for reduction
of the KMnO₄. The reason for the distinctly different molar
amount for Li₂CO₃ is the reduced solubility in aqueous HF.

| | VB1 | VB2 |
|---|---|---|
| SiO₂ / mmol | 4.446 | 4.348 |
| KMnO₄ (dopant, excess) / mmol | 7.7208 | 7.1121 |
| K₂CO₃ / mmol | 14.411 | |
| Li₂CO₃ / mmol | | 4.614 |

Since Li₂CO₃ (and LiF) is much more sparingly soluble in aqueous HF than K₂CO₃ (and KF), the free Mn⁴⁺ ion may not be stabilized in the solution since there are in fact no free Li ions available for complexation (experiment VB2). Instead, as well as LiF (main phase), the compound K₂SiF₆ is formed from the fractions of KMnO₄ that were used for doping. It is not ultimately possible to clarify the whereabouts of the Mn, but the absorption and emission measurements in FIG. 6 for VB2 show clearly that no Mn⁴⁺-doped phosphor was obtained, and not even in traces since neither emission nor absorption has been recorded for VB2. It was thus possible to show that the Li₂SiF₆:Mn⁴⁺ phosphor may not be synthesized via the known route of synthesis of K₂SiF₆:Mn⁴⁺. In other words, the phosphor Li₂SiF₆:Mn⁴⁺ is not formed from a precipitation reaction in aqueous hydrofluoric acid (HF) using the reactants Li₂CO₂, SiO₂ and a manganese source.

The product obtained from VB2, as shown in FIG. 6, does not show any absorption or any emission.

The working examples described in conjunction with the figures and features thereof may also be combined with one another in further working examples, even if such combinations are not shown explicitly in the figures. In addition, the working examples described in conjunction with the figures may have additional or alternative features according to the description in the general part.

### LIST OF REFERENCE NUMERALS

LED light-emitting diode
CRI color rendering index
LER luminous efficacy of radiation
rel. LER relative luminous efficacy of radiation
CCT correlated color temperature
FWHM spectral width of emission, full width at half maximum
ppm parts per million
VB comparative example
rI, Ir relative intensity
mol % mole percent
nm nanometers
° C. degrees Celsius
λ_{exc} excitation wavelength
λₘₐₓ emission maximum
λ_{dom} dominant wavelength

1. A phosphor having an empirical formula Li₂SiF₆:Mn⁴⁺.

2. The phosphor as claimed in claim 1, wherein the phosphor crystallizes in a trigonal crystal system.

3. The phosphor as claimed in claim 2, wherein the phosphor crystallizes in a P321 space group.

4. A process for preparing a phosphor having an empirical formula Li₂SiF₆:Mn⁴⁺ by a solid-state synthesis.

5. The process as claimed in claim 4, wherein the solid-state synthesis is performed under elevated pressure and at elevated temperature.

6. The process as claimed claim 4, wherein the solid-state synthesis is performed under an elevated pressure of 25 kbar to 85 kbar and within a temperature range between 500° C. and 1000° C.

7. The process as claimed in claim 4, wherein Li₂SiF₆ and A₂MnF₆, wherein A=Li, Na, K, Rb or Cs, are used as reactants.

8. The process as claimed in claim 7, wherein a molar ratio of Li₂SiF₆ to A₂MnF₆ is between 1:0.2 and 1:0.001.

9. A conversion light emitting diode (LED) comprising a phosphor having an empirical formula Li₂SiF₆:Mn⁴⁺.

10. The conversion LED as claimed in claim 9, comprising:
a semiconductor layer sequence configured to emit electromagnetic primary radiation; and
a conversion element comprising the phosphor, wherein the conversion element at least partly converts the electromagnetic primary radiation to electromagnetic secondary radiation.
